(19) United States
(12) Patent Application Publication
(10) Pub. No.: US 2026/0169062 A1
(43) Pub. Date: Jun. 18, 2026

(54) METHOD OF TESTING SEMICONDUCTOR DEVICES, CORRESPONDING TEST APPARATUS, PROBE CARD AND SEMICONDUCTOR WAFER

(71) Applicant: STMICROELECTRONICS INTERNATIONAL N.V., Geneva (CH)

(72) Inventor: Alberto PAGANI, Nova Milanese (IT)

(21) Appl. No.: 19/407,203

(22) Filed: Dec. 3, 2025

(30) Foreign Application Priority Data
Dec. 17, 2024 (IT) 102024000028752

(51) Int. Cl. G01R 31/28

(52) U.S. Cl. CPC G01R 31/2887; G01R 31/2884

(57) ABSTRACT

A method of testing semiconductor devices, corresponding test apparatus, probe card and semiconductor wafer are provided. An exemplary semiconductor wafer has pad structures providing electrical contact points for a plurality of integrated circuits embedded in the semiconductor wafer. The integrated circuits are electrically tested via test signals injected via a probe card. The probe card comprises an array of electrical probes configured to establish injection paths of test signals to a set of integrated circuits embedded in the semiconductor wafer in response to the array of electrical probes in the probe card. The probe card comprises at least one feedback probe configured to establish coupling with at least one alignment structure of the semiconductor wafer in response to the array of electrical probes being aligned with the respective array of pad structures to establish electrical contact therewith. The coupling provides feedback on alignment and electrical contact.

### CROSS REFERENCE TO RELATED APPLICATIONS

This application is a translation of and claims the priority benefit of Italian Patent Application Number 102024000028752, filed on Dec. 17, 2024, entitled “PROCEDIMENTO PER TESTARE DISPOSITIVI A SEMICONDUTTORE, APPARATO DI TEST, PROBE CARD E WAFER A SEMICONDUTTORE CORRISPONDENTI”, which is hereby incorporated by reference to the maximum extent allowable by law.

### TECHNICAL FIELD

The description relates to semiconductor devices and, more particularly, semiconductor device that may be applied to electrical test of (integrated circuit, IC) semiconductor devices.

### BACKGROUND

In conventional manufacturing processes of semiconductor devices, a semiconductor wafer is provided with a plurality of integrated circuits embedded therein.

Prior to singulating the semiconductor wafer into a plurality of semiconductor dice, the integrated circuits embedded therein are electrically tested in order to select functioning semiconductor dice and to discard die with functional/electrical defects.

To that effect, the semiconductor wafer is tested in a test apparatus via a probe card configured to electrically test the integrated circuits embedded in the semiconductor wafer.

The probe card is configured to test one or more semiconductor dice (that is, to electrically test the integrated circuits embedded therein) in the semiconductor wafer via an array of electrical probes that are configured to electrically contact corresponding pads provided at the (active) surface of the one or more semiconductor dice that are tested.

The probe card is aligned with respect to the pads under test and, subsequently, electrical contact is established between the probes in the probe card and the pads in order to facilitate electrical testing of the integrated circuits for which the pads provide electrical contact points.

The results of such a test step relies on a precise alignment of the probe card with respect to the pads to be tested.

In electrical test of pads provided with a relatively soft pad finishing, such contact between the probes in the probe card and the pads leaves a probe mark in the pad finishing that is used as feedback on the correct alignment of the probe card and the semiconductor wafer.

In electrical test of pads provided with a relatively hard pad finishing (as it is the case with nickel-palladium pad finishing) the probe mark formed in response to the contact with the probes in the probe card is hardly visible/detectable (or not detectable at all).

In such cases no information or feedback on the alignment and the electrical contact between the electrical probes and the pads under test is provided, undesirably reducing control over the electrical test step.

Document US20190204381 A1 provides background information in the related technological area.

### BRIEF SUMMARY

An object of one or more embodiments is to overcome the drawbacks discussed in the foregoing.

According to one or more embodiments, that object is achieved via a method having the features set forth in the claims that follow.

One or more embodiments also relate to a corresponding apparatus.

One or more embodiments relate to a probe card for use in such a method or in such an apparatus.

One or more embodiments relate to a semiconductor wafer for use in such a method or in such an apparatus.

The claims are an integral part of the technical teaching provided in respect of the embodiments.

Solutions as described herein involve electrically testing integrated circuits embedded in a semiconductor wafer via a probe card configured to inject into the integrated circuits test signals.

In solutions as described herein, the semiconductor wafer has provided at the active surface thereof alignment structures which facilitates providing feedback on alignment of the probe card with respect to the semiconductor wafer.

In solutions as described herein, a probe card is provided with at least one feedback probe configured to be coupled with the alignment structures provided at the (active) surface of the semiconductor wafer.

Solutions as described herein may involve forming a probe mark in a passivation or protection layer provided at the surface of the semiconductor wafer via the feedback probe in the probe card, wherein a probe mark formed at the alignment structures provide feedback on the (adequate) alignment of the probe card with respect to the semiconductor wafer.

Solutions as described herein may involve capacitively coupling one or more feedback probes in the probe card with an alignment structure provided at the surface of the semiconductor wafer, wherein the capacitive coupling may be probed in order to provide feedback on alignment of the probe card with respect to the semiconductor wafer.

### BRIEF DESCRIPTION OF THE DRAWINGS

One or more embodiments will now be described, by way of example only, with reference to the annexed figures, wherein:

FIGS. 1 and 2 (wherein FIG. 2 is an enlarged view of the portion of FIG. 1 indicated by the arrow II) are plan views illustrative of a semiconductor wafer to which embodiments of the present description may be applied,

FIGS. 3 and 4 are cross-sectional views illustrative of possible issues in electrical testing of a semiconductor wafer,

FIGS. 5A and 5B are schematic views illustrative of a semiconductor wafer and a portion of a corresponding test apparatus, respectively, according to embodiments of the present description,

FIGS. 6, 7A and 7B are cross-sectional views illustrative of an electrical test step according to embodiments of the present description,

FIGS. 8A and 8B are schematic views illustrative of a semiconductor wafer and a corresponding portion of a test apparatus, respectively, according to further embodiments of the present description,

FIG. 9 is a plan view illustrative of a semiconductor wafer according to further embodiments of the present description,

FIG. 10 is a cross-sectional view illustrative of a test step of a semiconductor wafer as illustrated in FIG. 9,

FIG. 11 is a schematic diagram illustrative of details of a portion of a test apparatus according to embodiments of the present description,

FIGS. 12A and 12B are schematic views illustrative of a semiconductor wafer and a corresponding test apparatus, respectively, according to further embodiments of the present description,

FIG. 13 is a cross-sectional view illustrative of a test step of a semiconductor wafer as illustrated in FIG. 12A,

FIG. 14 is a schematic diagram illustrative of details of a portion of a test apparatus according to embodiments of the present description,

FIGS. 15A and 15B are schematic views illustrative of a semiconductor wafer and a corresponding portion of a test apparatus, respectively, according to further embodiments of the present description, and

FIG. 16 is a cross-sectional view exemplary of a test step of a semiconductor wafer as illustrated in FIG. 15A.

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

### DETAILED DESCRIPTION

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

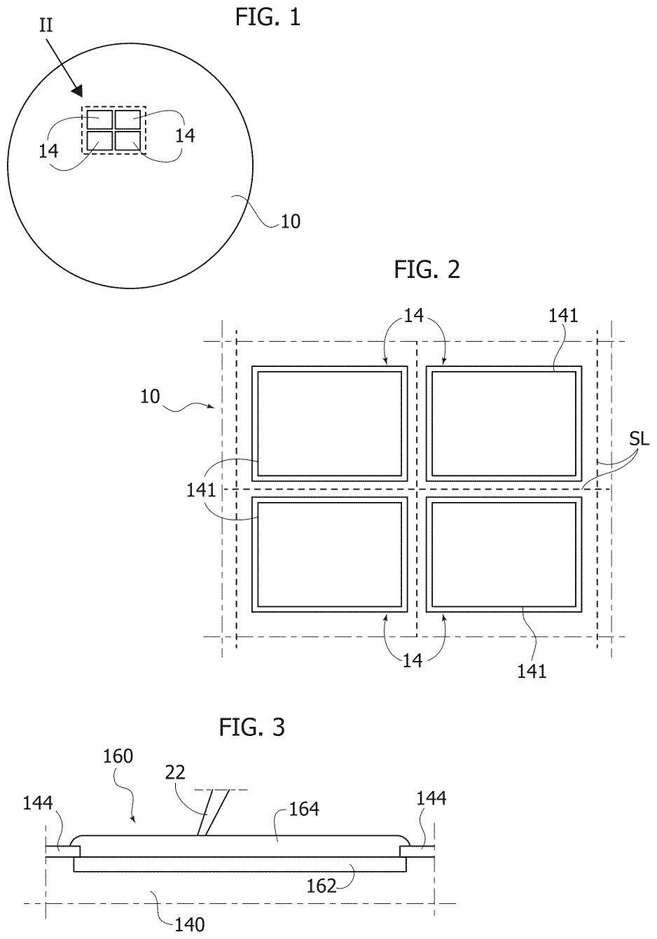

FIGS. 1 and 2 are plan views (wherein FIG. 2 is an enlarged view of the portion of FIG. 1 indicated by the arrow II) illustrative of a semiconductor (Si, SiC, GaN, for instance) wafer 10 having embedded therein (in any way known in the art) a plurality of integrated circuits, ICs.

As known to those skilled in the art, a semiconductor wafer 10 as illustrated in FIG. 1 is configured to be partitioned into a plurality of semiconductor dice or chips 14 (the terms die/dice and chip/chips are herein regarded as synonymous) in a singulation step wherein the wafer is cut (via sawing, or laser for instance) at scribe lines SL.

FIG. 2 is illustrative of a portion of a semiconductor wafer 10; as illustrated, scribe lines SL define a plurality of regions of the semiconductor wafer 10, each comprising at least one integrated circuit, that, subsequently to singulation, provide corresponding semiconductor dice 14.

As illustrated in FIG. 2, each wafer region between adjacent scribe lines SL may be provided with a seal ring 141 in order to reduce mechanical stress on the wafer portion and the integrated circuit(s) embedded therein that may develop in response to the singulation step.

In the following, regions of the semiconductor wafer defined by the scribe lines SL will be referred to as semiconductor dice (indicated with the reference 14 in the figures) being otherwise understood that proper, individual (singulated) semiconductor dice 14 are obtained subsequently to singulation of the semiconductor wafer 10.

Providing a semiconductor wafer 10 as discussed so far is otherwise conventional in the art, which makes it unnecessary to provide a more detailed description herein.

As mentioned, prior to singulating the semiconductor wafer 10, the (at least one) integrated circuit embedded in each semiconductor die 14 is tested in order to detect possible functional defects, electrical defects, for instance, in a processing step oftentimes referred to as electrical wafer sorting, EWS. Such a test step facilitates selecting the semiconductor dice 14 with properly functioning integrated circuit(s) embedded therein in order to perform further processing steps (packaging, for instance) only on functioning semiconductor dice 14.

To that effect, the semiconductor wafer 10 is tested in a test apparatus prior to singulation. As known to those skilled in the art, such a test apparatus includes:
a wafer holder in a prober equipment (not illustrated in the figures for simplicity), configured to receive the semiconductor wafer 10 that is intended to test, and
a probe card associated to an automatic test equipment or tester (not illustrated in the figures for simplicity) configured to electrically test the integrated circuits embedded in the semiconductor wafer 10.

The probe card comprises a plurality of electrical probes (contacts) configured to contact corresponding pads provided at the (active) surface of the semiconductor wafer (such pads are not visible in FIGS. 1 and 2 for simplicity).

That is, a probe card comprises a plurality of probes configured to contact corresponding input/output pads of the (at least one) integrated circuit embedded in one or more semiconductor dice 14, thus establishing an electrical coupling between the integrated circuits and test circuitry in the test apparatus. Test signals are thus injected into the integrated circuits facilitated by the electrical coupling between the probes in the probe card and the pads at the active surface of the semiconductor wafer 10.

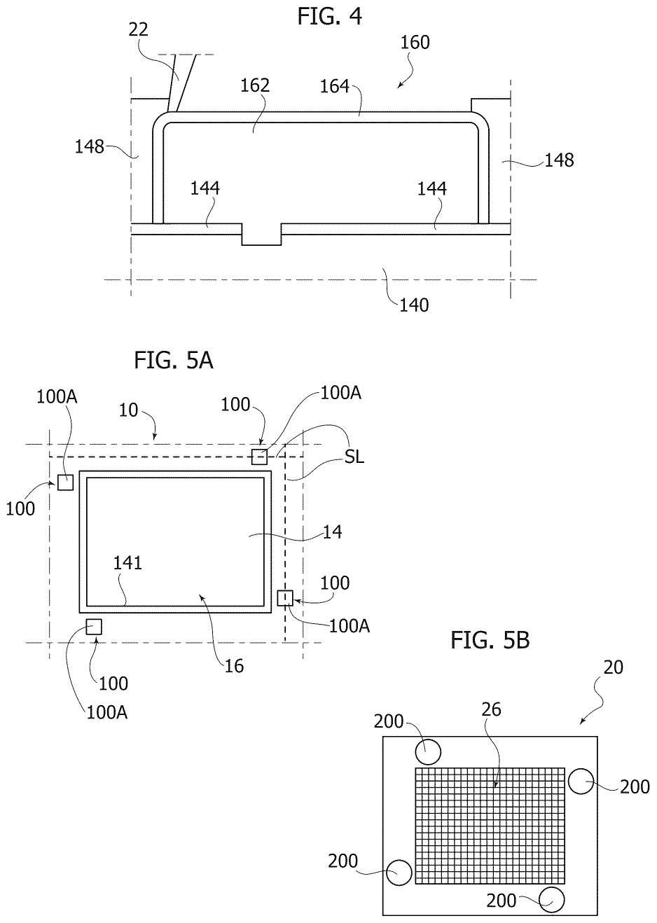

FIGS. 3 and 4 are cross-sectional views illustrative of details of such an (electrical) test step.

FIG. 3 is illustrative of a pad structure 160 that is tested via an electrical probe 22 (an electrical probe of a probe card, for instance).

As illustrated, the pad structure 160 may comprise a pad 162 of a first electrically conductive material (a metallic material such as copper, for instance) embedded in the dielectric material 140 of the semiconductor die 14 and electrically coupled to the integrated circuit embedded in the dielectric material 140.

A pad finishing (or pad coating) 164 is provided onto the pad 162. The pad finishing 164 may be an aluminium pad finishing 164 (forming a so-called Al-cap finishing 164 for the pad 162) or a nickel-palladium, NiPd, finishing 164, for instance.

As illustrated, a passivation layer or a protection layer 144 may be provided at the active surface of the semiconductor die 14 (that is, the top surface in the figures) to provide electrical insulation to the semiconductor die 14 and the integrated circuit embedded therein. As illustrated, the passivation layer 144 may have openings at the pad structures 160 that leave exposed the pad finishing 164 provided onto the pads 162.

The integrated circuit(s) in the semiconductor die 14 is tested by electrically contacting the pads 160 at the active surface of the semiconductor die 14 with respective electrical probes 22 in the probe card. More in details, a test step is performed by aligning the probe card with respect to the pad structures 160 at the active surface of the semiconductor die (or dice) 14 under test, and by establishing electrical contact between the electrical probes 22 in the probe card and the pad structures 160.

As mentioned previously, the outcome of such a test step depends on the alignment of the probe card with respect to the semiconductor wafer 10. More precisely, the array of electrical probes in the probe card are to be aligned with the array of pad structures 160 under test.

In pad structures 160 comprising a pad finishing 164 of a relatively soft material (an Al-cap pad finishing 164, for instance) the contact between the probe 22 and the pad finishing 164 causes a probe mark to form in the (relatively soft) pad finishing 164. Such a probe mark is used as visual/optical confirmation that the pad structure 160 has been tested and as a reference point for alignment of the probe card of the test apparatus.

However, when relatively hard materials are used to form the pad finishing 164, an undetectable probe mark may form in response to the contact between the (hard) pad finishing 164 and the probe 22, which fails to provide visual feedback on alignment (or a reference point) during electrical testing of the semiconductor wafer 10.

This may be the case, for instance, when NiPd pad finishing 164 is desired for the pads 160 of the semiconductor dice 14. A NiPd pad finishing 164 may be formed, for instance, by growing via electroless deposition a first layer of nickel onto the pad 162 and, subsequently, by growing a palladium layer (having a thickness less than 0.5 microns, for instance) onto the layer of nickel. Contact between electrical probe 22 and such a NiPd pad finishing 164 is observed to leave (almost) undetectable probe marks, thus providing no information on the alignment and the electrical contact between the electrical probes 22 and the pad structures 160 under test.

For certain “hard” pad finishing 164 the issue may be overcome by providing the electrical probes 22 with a tip (that is, the terminal portion of the electrical probe 22 configured to contact the pad finishing 164) of a “hard” material, in order to facilitate leaving a probe mark also in case of a “hard” pad finishing 164. However, while advantageous in certain cases, such solutions may have some drawbacks when applied to electrically test pad structures 160 provided with a NiPd pad finishing 164. In fact, the relatively thin Pd layer (less than 0.5 microns, for instance) may undesirably be removed in response to the contact between such an electrical probe and the pad finishing 164, undesirably leaving the Ni material exposed at the surface of the pad structure 160.

FIG. 4 is illustrative of a pad structure 160 embedded in a further electrically insulating layer 148. The further electrically insulating layer 148 may be a polyimide (PI) layer, for instance, provided at the active surface of the semiconductor wafer 10 in order to protect the active surface from scratches or, more generally, damage, which may undesirably result from further processing of the semiconductor wafer 10 (or the semiconductor dice 14 obtained in response to singulation of the semiconductor wafer 10).

As illustrated, the polyimide layer 148 has apertures that leave uncovered pad structures 160 at the active surface of the semiconductor wafer 10 so to facilitate providing electrical contact points to the integrated circuits embedded in the semiconductor wafer 10. As illustrated in FIG. 4, misalignment of the probe card may undesirably result in an electrical probe 22 contacting and damaging the polyimide layer 148, thus compromising the protective effect of the polyimide layer 148.

Solutions as described herein involve electrically testing integrated circuits embedded in a semiconductor wafer via a probe card configured to inject into the integrated circuits test signals.

In solutions as described herein, the semiconductor wafer has provided at the active surface thereof alignment structures which facilitates providing feedback on alignment of the probe card with respect to the semiconductor wafer.

In solutions as described herein, a probe card is provided with at least one feedback probe configured to be coupled with the alignment structures provided at the (active) surface of the semiconductor wafer.

Solutions as described herein may involve forming a probe mark in a passivation or protection layer provided at the surface of the semiconductor wafer via the feedback probe in the probe card, wherein a probe mark formed at the alignment structures provide feedback on the (adequate) alignment of the probe card with respect to the semiconductor wafer.

Solutions as described herein may involve capacitively coupling one or more feedback probes in the probe card with an alignment structure provided at the surface of the semiconductor wafer, wherein the capacitive coupling may be probed (detected or measured, for instance) in order to provide feedback on alignment of the probe card with respect to the semiconductor wafer.

More in details, embodiments as described in the following involve providing a semiconductor wafer 10 having at a surface thereof pad structures 160 that provide electrical contact points for a plurality of integrated circuits embedded in the semiconductor wafer 10.

The integrated circuits embedded in the semiconductor wafer 10 are electrically tested via test signals injected thereinto via a probe card. The probe card comprises an array of electrical probes 22 configured to establish injection paths of test signals to a set of integrated circuits embedded in the semiconductor wafer 10 in response to the array of electrical probes 22 in the probe card aligning and establishing electrical contact with a respective array of pad structures 160 at the surface of the semiconductor wafer 10.

The pad structures 160 in the respective array of pad structures 160 provide electrical contact points to the set of integrated circuits under test.

Advantageously, the probe card comprises at least one feedback probe configured to establish coupling with at least one alignment structure provided at the (active) surface of the semiconductor wafer 10 in response to the array of electrical probes 22 in the probe card being aligned with the respective array of pad structures 160 at the surface of the semiconductor wafer 10 to establish electrical contact therewith.

The coupling of the at least one feedback probe and the at least one alignment structure at the surface of the semiconductor wafer 10 provides feedback on alignment and electrical contact between the array of electrical probes 22 in the probe card and the respective array of pad structures 160 at the surface of the semiconductor wafer 10.

Solutions as following may be implemented via a test apparatus comprising:
a wafer holder configured to receive such a semiconductor wafer 10 (comprising one or more alignment structures) candidate for being tested, and
a probe card as described herein (comprising at least one feedback probe) for electrically testing the integrated circuits embedded in the semiconductor wafer 10.

FIGS. 5A and 5B are schematic views illustrative of a portion of a semiconductor wafer 10 and a probe card 20, respectively, according to embodiments of the present description.

The schematic views of FIGS. 5A and 5B illustrate (a portion of) the surface of a semiconductor wafer 10 and a surface of a probe card 20 that are configured to face each other (that is, the two surfaces are arranged face-to-face) when performing the electrical test.

The portion of semiconductor wafer 10 illustrated in FIG. 5A comprises one semiconductor die 14 (having at least one IC embedded therein) having scribe lines SL (that is, regions of the semiconductor wafer 10 that are intended to be at least partially removed during singulation) running at the periphery of the semiconductor die 14.

The semiconductor die 14 has a plurality of I/O pads (having a pad structure 160 as exemplified in FIG. 3 or 4, for instance) exposed at the active surface of the semiconductor die 14; for simplicity, the pad structures 160 at the active surface of the semiconductor die 14 are not visible FIG. 5A.

The pad structures 160 are arranged at the active surface of the semiconductor die 14 according to a desired pad pattern 16 (depending, for instance, on the particular design of the IC(s) embedded in the die 14).

FIG. 5B is a schematic view illustrative of a probe card 20 that can be used for electrically testing a semiconductor die 14 as illustrated in FIG. 5A.

Such a probe card 20 may be included in a testing apparatus otherwise conventional in the art.

With reference to FIG. 5B, the probe card 20 comprises an array 26 of electrical probes 22, arranged according to a probe pattern. The array 26 of (electrical) probes 22 is arranged to correspond to the array 16 of pad structures 160 at the active surface of the semiconductor die 14. In other words, the electrical probes 22 in the array 26 of electrical probes 22 are configured to concurrently contact corresponding pads 160 in the array 16 of pad structures 160 at the active surface the semiconductor die (or dice) 14 when the semiconductor die 14 is electrically tested via the probe card 20.

With reference to FIGS. 5A and 5B, one or more alignment structures 100 are provided at the active surface of the semiconductor wafer 10 that are configured to be coupled to respective one or more feedback probes 200 comprised in the probe card 20. That is, a probe card 20 as exemplified in FIG. 5B comprises, in addition to the array 26 of electrical probes 22, one or more feedback probes 200 configured to be coupled to corresponding alignment structures 100 at the active surface of the semiconductor wafer 10.

It is noted that a probe card 20 may be configured to electrically test more than one semiconductor die 14 concurrently. In such embodiments, the array 26 of electrical probes 22 are configured to electrically contact an array 16 of pad structures 160 that provide electrical contact points to the integrated circuits embedded in the (more than one) semiconductor dice 14. At least one alignment structure 100 may be provided at the (active) surface of the semiconductor wafer 10 for each group of semiconductor dice 14 that are concurrently tested via the probe card 20.

For simplicity and ease of explanation, in the following reference will be made to a probe card 20 configured to electrically test the integrated circuit(s) embedded in one semiconductor die 14.

In one or more embodiments the alignment structure 100 may comprise an alignment pad 100A having one or more electrically insulating layer thereon (a passivation layer 144 and/or a protective layer 148), wherein the one or more electrically insulating layers 144, provided 148 on the alignment pad 100A are configured to be marked by a feedback probe 200 in the probe card 20.

A pattern of alignment pads 100A as exemplified in FIG. 5A may advantageously be replicated over the surface of the semiconductor wafer 10; as the person skilled in the art may appreciate, replicating a pattern as exemplified in FIG. 5A results in four alignment pads 100A at the crossing of two scribe lines SL.

The particular pattern illustrated in FIG. 5A is otherwise merely exemplary of a possible pattern; several different patterns of alignment pads 100A are possible.

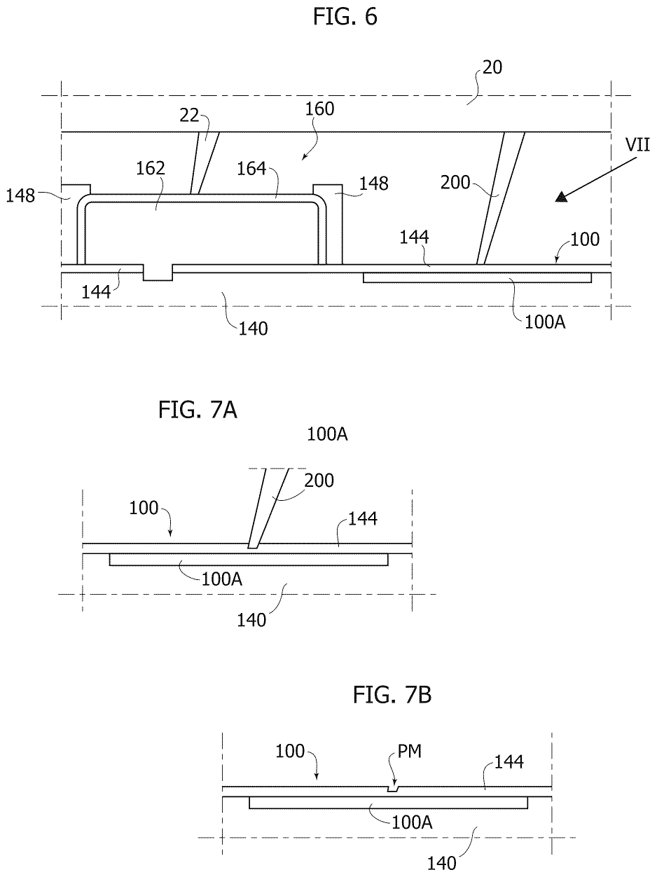

FIGS. 6, 7A and 7B are cross-sectional views (wherein FIGS. 7A and 7B are enlarged views of the portion of FIG. 6 indicated by the arrow VII) illustrative of details of a test step of a semiconductor wafer 10 as illustrated in FIG. 5A via a probe card 20 as illustrated in FIG. 5B.

As illustrated in FIG. 6, a probe card 20 with the array of electrical probes 22 is aligned with an array 16 of pad structures 160 at the active surface of the semiconductor wafer 10.

As illustrated, the alignment pad 100A is covered with a passivation layer 144; as mentioned previously, such a passivation layer 144 is conventionally provided at the (active) surface of the semiconductor wafer 10 with apertures at the pad structures 160 at the active surface of the semiconductor dice 14. The passivation layer 144 may be provided also at scribe lines SL covering the dielectric material 140 of the semiconductor wafer 10, and, consequently, covering the pad 100A in the alignment structure 100.

It is noted that the protection layer 148 may be absent.

Still referring to FIG. 6, in the test step, the electrical probes 22 of the probe card 20 are arranged in electrical contact with the pad structures 160 in the array 26 on the active surface of the semiconductor wafer 10.

The test apparatus (not illustrated in the figures for simplicity) comprises test circuitry coupled to the electrical probes 22 that is configured to inject test signals into the integrated circuits in the semiconductor dice 14 via the electrical contact between the electrical probes 22 and the pad structures 160.

Concurrently, in embodiments as exemplified in FIG. 6, a coupling is established between the (additional) feedback probe (or probes) 200 and the alignment pad 100A in the alignment structure(s) 100. A probe mark is formed in the passivation or protection layer 144 at the alignment pad 100A that provides feedback on the alignment and contact of the electrical probes 22 and the pad structures 160.

Further details of such test step are illustrated in FIGS. 7A and 7B. As illustrated in FIG. 7A, the feedback probe 200 may penetrate the passivation layer 144, possibly contacting the alignment pad 100A in the alignment structure 100 that is beneath the passivation layer 144.

As illustrated in FIG. 7B, the test probe 200 penetrating the passivation layer 144 leaves a probe mark PM in the passivation layer 144. Such a probe mark PM provides visual confirmation of the test step performed on the semiconductor die or dice 14, that is, the electrical test performed for the integrated circuits embedded therein.

A probe mark PM as described in the foregoing may be used for visual confirmation of the adequate alignment of the probe card 20 with respect to the semiconductor die or dice 14 under electrical test, that is, of the adequate alignment of the array 26 of electrical probes 22 with respect to the array 16 of pad structures 160, by verifying that a probe mark PM is formed at the alignment pad 100A in the alignment structure 100.

Similarly, in embodiments where the probe card 20 comprises two test probes 200 (in addition to the electrical probes 22 in the array 26 of electrical probes), two probe marks PM may be formed in the passivation layer 144 at alignment pads 100A in two corresponding alignment structures 100 at the active surface of the semiconductor wafer 10. Having more than one (two, for instance) probe marks PM formed in the passivation layer 144 may be advantageous in so far as they may be used as visual feedback on the positioning and orientation of the probe card 20 with respect to the semiconductor wafer 10.

Referring again to FIG. 6, the pad structure 160 illustrated therein is embedded in a further electrically insulating layer 148. As mentioned, the further electrically insulating layer 148 may comprise, for instance, a polyimide (PI) layer.

In one or more embodiments, the further electrically insulating layer 148 may be provided also at the alignment pad 100A in the alignment structure 100 (located at the scribe lines SL of the semiconductor wafer 10 as illustrated in FIG. 5A, for instance) thus covering the passivation layer 144 provided thereon. In such embodiments, the feedback probe 200 may be configured to form a probe mark PM in the passivation layer 144 and/or in the further electrically insulating layer 148 (a polyimide layer, for instance), at the alignment pad 100A of the alignment structure(s) 100, in response to the probe card 20 being aligned with the pad structures 160 to establish electrical contact.

In embodiments as described so far, alignment structures 100 are provided at the scribe lines SL; this may be advantageous in so far as alignment structures 100 at scribe lines SL do not interfere with the array 16 of (functional) pad structures 160 of the semiconductor dice 14, that is, alignment structures 100 do not take up space at the active surface of the semiconductor dice 14. It is noted that alignment structures 100 provided at the scribe lines SL may be at least partially removed during singulation of the semiconductor wafer 10 (performed subsequently to electrical testing).

In one or more embodiments, the alignment pad 100A in the alignment structures 100 may be a dummy pad 100A, that is, a pad 100A that is electrically decoupled from the integrated circuits embedded in the semiconductor die 14 and is not intended to be used as I/O pads therefor.

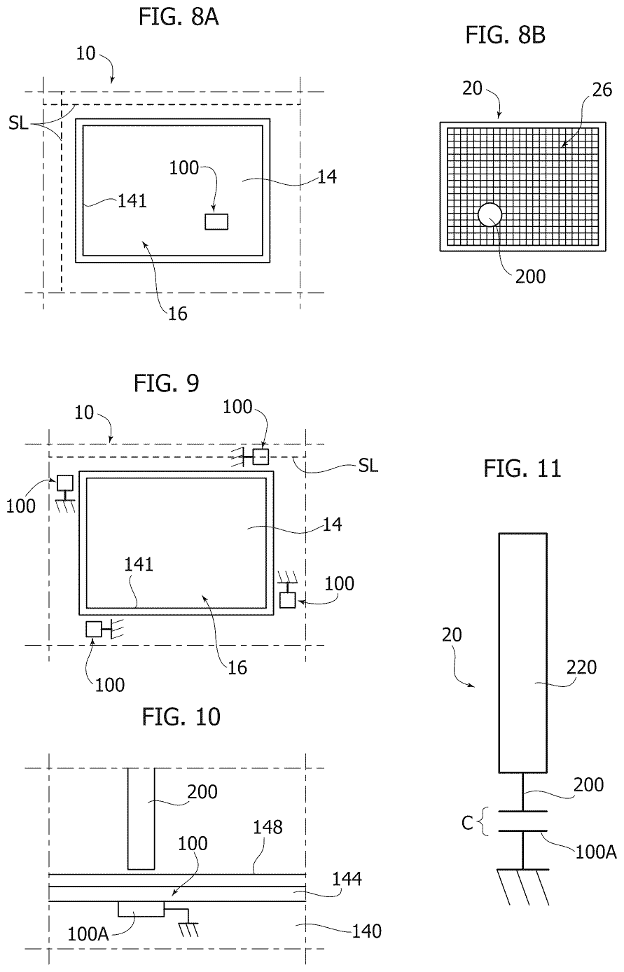

As illustrated in FIGS. 8A and 8B, alignment structure(s) 100 as described in the foregoing may be provided also at the active surface of the semiconductor dice 14, inwardly of the seal ring 141, for instance.

FIG. 8A is illustrative of a portion of a semiconductor wafer 10 provided with (at least) one alignment structure 100 at the active surface of a semiconductor die 14, that is, inwardly of the seal ring 141.

The alignment structure 100 may comprise a dummy pad 100A, that is, a pad that is not used for providing (I/O) electrical contact points to the integrated circuit(s) in the semiconductor die 14.

FIG. 8B is a schematic view of a probe card 20 that may be used for (electrical) testing a semiconductor wafer 10 as illustrated in FIG. 8A. As illustrated, one or more feedback probes 200 are arranged among the electrical probes 22 in the array 26 of electrical probes 22 configured to electrically contact the array 16 of pad structures 160 at the active surface of the semiconductor die 14. The feedback probe(s) 200 are configured to form a probe mark at the (dummy) alignment pad 100A in the alignment structures 100 provided at the active surface of the semiconductor die 14 (inwardly of the seal ring 141, for instance).

Again, the schematic views of FIGS. 8A and 8B illustrate (a portion of) the surface of a semiconductor wafer 10 and a surface of a probe card 20 that are configured to face each other (that is, the two surfaces are arranged face-to-face) when performing the electrical test.

In other words, in embodiments as described in the foregoing, the at least one alignment structure 100 may comprise an alignment pad 100A having at least one electrically insulating layer thereon (a passivation layer 144 and/or a protective polyimide layer 148) provided at the (active) surface of the semiconductor wafer 10.

The probe card 20 comprises at least one feedback probe 200 that is configured to form a probe mark PM in the at least one electrically insulating layer 144, 148 in response to the array 26 of electrical probes 22 in the probe card 20 being aligned with the respective array 16 of pad structures 160 at the surface of the semiconductor wafer 10 to establish electrical contact therewith. The probe mark PM provides feedback on alignment and electrical contact between the array 26 of electrical probes 22 in the probe card 20 and the corresponding array 16 of pad structures 160 at the surface of the semiconductor wafer 10.

FIG. 9 is a plan view illustrative of a portion of a semiconductor wafer 100 provided with one or more alignment structures 100 according to further embodiments of the present description.

As illustrated, the alignment structures 100 may be provided at the scribe lines SL, that is, outwardly of the seal ring 141 of a semiconductor die 14 in the wafer 10.

As schematically illustrated, the alignment structures 100 may comprise an alignment pad 100A electrically coupled to ground. The alignment pad 100A may be grounded facilitated by a probe chuck onto which the semiconductor wafer 10 under test is arranged. To that effect, electrically conductive formations (metallic layers and vias, and/or through silicon vias, TSV, for instance) may be formed in the dielectric material 140 and/or in the semiconductor wafer 10 (at the scribe lines SL, for instance) to facilitate electrically coupling the alignment pad 100A in the alignment structure(s) 100 to the probe chuck (and to ground).

A probe card 20 as exemplified in FIG. 5B may be used for testing a semiconductor wafer 10 as described with reference to FIG. 9; as already discussed, the probe card 20 comprises:
an array 26 of electrical probes 22 configured to electrically test the pad structures 160 at the active surface of the semiconductor wafer 10 (provided at the active surface of the semiconductor dice 14, inwardly of the seal ring 141, for instance), and
at least one feedback probe 200 (in addition to the electrical probes 22 in the array 26 of electrical probes 22) at a peripheral region of the probe card 20 (as schematically illustrated in FIG. 5A) and configured to be coupled to an alignment structure 100.

FIG. 10 is a cross-sectional view illustrative of a test step wherein a probe card 20 comprising one or more feedback probes 200 as illustrated in FIG. 5B is used to test a semiconductor wafer 10 as illustrated in FIG. 9.

Similarly to what has been described previously, the electrical probes 22 in the array 26 of electrical probes 22 are aligned to establish electrical contact with the pad structures 160 in the array 16 of pad structures 160 under test, and, concurrently, a feedback probe 200 in the probe card 20 is arranged over the pad 100A in the alignment structure 100, in proximity thereof.

The passivation layer 144 or the further passivation layer 148 (a polyimide, PI, layer, for instance) or both layers 144, 148, as illustrated in FIG. 10, may be provided at the position of the alignment structure 100.

The (electrically conductive) tip of the feedback probe 200 and the alignment pad 100A in the alignment structure 100 form a capacitive element C that may be probed (detected or measured, for instance) via test circuitry associated to the feedback probe 200 provided in the test apparatus or in the probe card 20.

It is noted that, as illustrated in FIG. 10, the feedback probe 200 may probe the capacitive coupling C without touching the passivation layer(s) 144, 148 provided over the alignment pad 100A.

FIG. 11 is a schematic view of the circuit formed in a test step as exemplified in FIG. 10.

The alignment pad 100A in the alignment structure 100 and the tip of the feedback probe 200 provide a capacitive element C or, said otherwise, are capacitively coupled. The test apparatus or the probe card 20 may be provided with test circuitry 220 associated with the feedback probe 200 and configured to probe the capacitive coupling between the feedback probe 200 and the alignment pad 100A in the alignment structure 100.

For instance, the test circuitry 220 may be configured to measure (a value indicative of) the capacitance C of the capacitive coupling between the feedback probe 200 and the alignment pad 100A in the alignment structure 100.

As those skilled in the art may appreciate, the measured value may vary as a function of the relative position of the feedback probe 200 and the alignment pad 100A in the alignment structure 100. Said otherwise, the measured value is a function of the positioning/alignment of the feedback probe 200 (and, consequently, of the array 26 of electrical probes 22 in the probe card 20) with respect to the alignment structure 100 (and correspondingly, with respect to the array 16 of pad structures 160 at the surface of the semiconductor wafer 10).

The measured capacitance C thus gives feedback on the positioning and alignment of the array 26 of electrical probes in the probe card 20 with respect to the array 16 of pad structures 160 at the surface of the semiconductor wafer 10.

The test apparatus may be configured for adjusting alignment of the probe card 20 with respect to the array 16 of pad structures 160 as a function of the measured value of capacitance C, that is, as a function of the feedback provided by the coupling between the feedback probe(s) 200 and the alignment structure(s) 100.

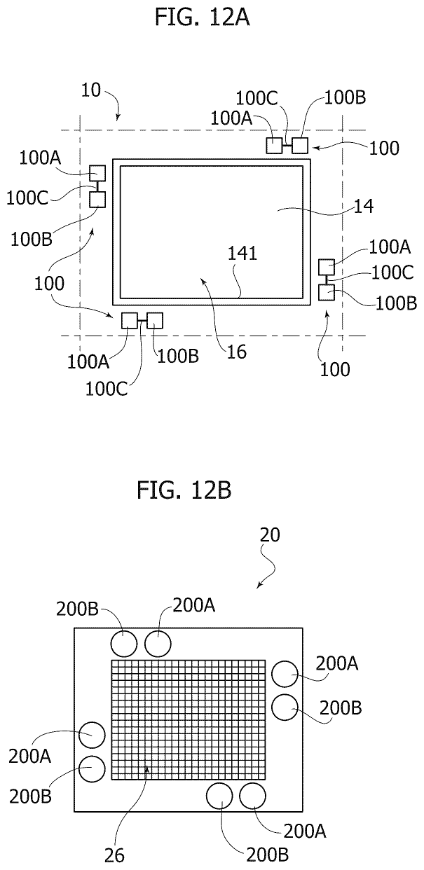

FIGS. 12A and 12B are illustrative of further embodiments of the present description where one or more alignment structures 100 are provided at the active surface of a semiconductor wafer 10 (at the scribe lines SL, for instance) and are configured to be probed via a probe card 20.

Also in this case, the schematic views of FIGS. 12A and 12B illustrate (a portion of) the surface of a semiconductor wafer 10 and a surface of a probe card 20 that are configured to face each other (that is, the two surfaces are arranged face-to-face) when performing the electrical test.

As illustrated in FIG. 12A, the alignment structure(s) 100 may comprise a first 100A and a second 100B alignment pad electrically coupled via an electrically conductive trace 100C. Providing an alignment structure 100 as illustrated in FIG. 12A may be done in any way known in the art.

The first 100A and the second 100B alignment pad in the alignment structure 100 may be dummy pads, that is, pads that are electrically decoupled from the integrated circuits embedded in the semiconductor wafer 10.

FIG. 12B is illustrative of a probe card 20 that may be used for testing a semiconductor wafer 10 as illustrated in FIG. 12A (that is, to electrically test the integrated circuits embedded therein).

As illustrated, the probe card 20 comprises an array 26 of electrical probes 22 configured to electrically contact the pad structures 160 in the array 16 of pad structures at the active surface of the semiconductor wafer 10 under test.

The probe card 20 comprises feedback probes 200 configured to be coupled with corresponding alignment structures 100 provided at the active surface of the semiconductor wafer 10. More in detail, the probe card may comprise a first 200A and a second 200B feedback probe for each of the alignment structures 100 provided for the array 16 of pad structures 160.

In the embodiments exemplified in FIGS. 12A and 12B, the alignment structures are located at the scribe lines SL (outwardly of the seal ring 141, for instance) and, correspondingly, the first and second test probes 200A, 200B are located outwardly of the array 26 of electrical probes 22 configured to electrically test the pad structures 160.

In one or more embodiments, the first 200A and the second 200B feedback probes may be configured to establish a current flow in the alignment structures 100 to provide feedback on the alignment of the probe card 20 with respect to the array 16 of pad structures 160. For instance, an electrical current may flow from the first feedback probe 200A through the first alignment structure 100A, the electrically conductive trace 100C, the second alignment structure 100B, to the second feedback probe 200B.

FIG. 13 is a cross-sectional view illustrative of a test step wherein a probe card 20 as exemplified in FIG. 12B is used to electrically test a semiconductor wafer 10 as illustrated in FIG. 12A.

Similarly to what has been described previously, the electrical probes 22 in the array 26 of electrical probes 22 are aligned to establish electrical contact with the pad structures 160 in the array 16 of pad structures 160 under test at the active surface of the semiconductor wafer 10 and, concurrently, first 200A and second 200B test probes in the probe card 20 are arranged over the first 100A and the second 100B alignment pad, respectively, in the (at least one) alignment structure 100.

As illustrated in FIG. 13, both passivation layer 144 and the further passivation layer 148 (a polyimide, PI, layer, for instance) may be provided at the position of the alignment structure 100, over the first 100A and the second alignment pads, as well as over the electrically conductive trace 100C providing electrical coupling therebetween.

As illustrated:
the first feedback probe 200A is capacitively coupled with the first alignment pad 100A in the alignment structure 100,
the second feedback probe 200B is capacitively coupled with the second alignment pad 100B in the alignment structure 100, and
the first 100A and the second 100B alignment pad in the alignment structure 100 are electrically coupled via the electrically conductive trace 100C.

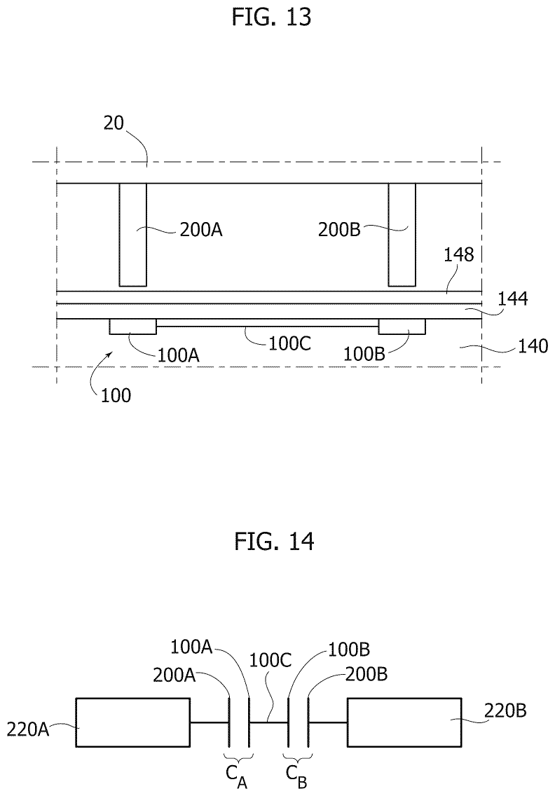

An equivalent circuit formed by such coupling of the feedback probes 200A, 200B with the alignment pads 100A, 100B in the alignment structure 100A is schematically illustrated in FIG. 14.

As illustrated in FIG. 14:
the first alignment pad 100A in the alignment structure 100 and the first feedback probe 200A provide a first capacitive element C_{A}, and
the second alignment pad 100B in the alignment structure 100 and the second feedback probe 200B provide a second capacitive element C_{B}.

The first C_{A} and the second C_{B} capacitive element are electrically coupled via the electrically conductive trace 100C or, said otherwise, are coupled in series.

The test apparatus or the probe card 20 may be provided with test circuitry 220A, 220B associated with the feedback probes 200A, 200B that are configured to probe (measure, sense or detect, for instance) the capacitive couplings between the feedback probes 200A, 200B and the alignment pads 100A, 100B in the alignment structure 100.

In one or more embodiments as exemplified in FIG. 14, the test circuitry may comprise transmitting (TX) test circuitry 220A associated to the first feedback probe 200A and receiving (RX) test circuitry 220B associated to the second feedback probe 200B. The TX test circuitry 220A may be configured to send a probe signal which propagates via the capacitive couplings C_{A}, C_{B} between the first/second feedback probe 200A/200B and the first/second alignment pad 100A/100B in the alignment structure 100. The probe signal may be received via the RX test circuitry 220B and used to measure a value indicative of the capacitances of the capacitive couplings.

More generally, the test circuitry 220A, 220B may be configured to probe the capacitive couplings between the first feedback probe 200A and the first alignment pad 100A in the alignment structure 100 and the second feedback probe 200B and the second alignment pad 100B in the alignment structure 100.

The capacitive couplings may vary as a function of the relative position of the feedback probes 200A, 200B and the alignment pads 100A, 100B in the alignment structure 100. Said otherwise, the result of probing (via test circuitry 220A, 220B) the capacitive couplings is a function of the positioning/alignment of the feedback probes 200A, 200B (and, consequently, of the array 26 of electrical probes 22 in the probe card 20) with respect to the alignment structure 100 (and consequently, with respect to the semiconductor die or dice 14 or the portion of semiconductor wafer 10 under test).

That is, probing the capacitive couplings gives feedback on the positioning and alignment of the array of electrical probes 22 in the probe card 20 with respect to the array 16 of pad structures 160 at the surface of the semiconductor wafer 10 under test.

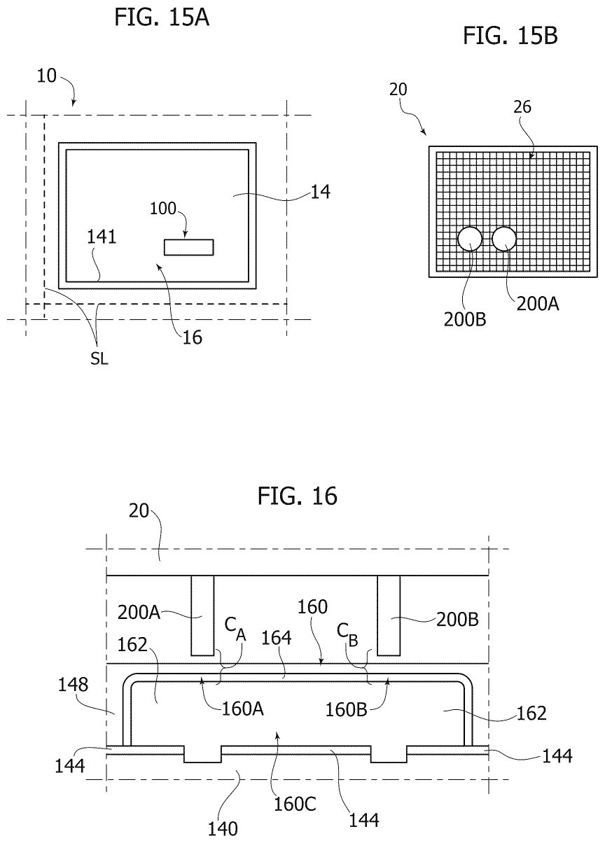

FIGS. 15A and 15B are illustrative of a portion of a semiconductor wafer 10 and a probe card 20 according to further embodiments of the present description wherein the alignment structure 100 is provided at the active surface of a semiconductor die 14, that is, inwardly of the seal ring 141. Correspondingly, as illustrated in FIG. 15B, the probe card 20 has feedback probes 200A, 200B provided among the electrical probes 22 in the array 26 of electrical probes 22.

The alignment structure 100 may comprise, similarly to what has been described in the foregoing, first 100A and second 100B alignment pads electrically coupled via an electrically conductive trace (as illustrated in FIG. 13, for instance) configured to be (capacitively) coupled to the first 200A and the second 200B feedback probes provided in the probe card 20. The first and the second alignment pads 100A, 100B in the alignment structure 100 may be dummy pads, that is pads that are not used as I/O electrical contact points for the integrated circuits under test and that are electrically decoupled therefrom.

In one or more embodiments, a portion of a redistribution layer provided at the surface of the semiconductor die 14 may be used as alignment structure in order to have feedback on alignment and electrical contact between the electrical probes 22 and the pad structures 160 under test.

A redistribution layer comprises a pattern of electrically conductive traces (and possibly vias) that provides input/output (I/O) pads of an integrated circuit available in other locations.

FIG. 16 is a cross-sectional view illustrative of such embodiments. As illustrated, a portion of an electrically conductive redistribution layer (indicated with the same reference 160 used for the pad structures for simplicity) is provided at the surface of the semiconductor wafer 10.

The redistribution layer 160 may comprise copper material 162 having an optional finishing layer 164 (a NiPd finishing layer, for instance) grown thereon.

A protective (polyimide) layer 148 may be provided at the surface of the semiconductor wafer 10, to provide protection and electrical insulation to the electrically conductive redistribution layer 160.

As illustrated, similarly to what has been described with reference to FIG. 13, for instance, a first 200A and a second 200B feedback probe may be capacitively coupled to a first 160A and a second 160B portion of the redistribution layer 160, respectively, with a further portion 160C of the redistribution layer 160 electrically coupling the first 160A and the second 160B portion thereof.

In other words, regions 160A, 160B of a redistribution layer at the surface of the semiconductor wafer 10 may provide the first 100A and second 100B alignment pads as well as the electrically conductive trace 100C in an alignment structure 100 that can be used for feedback on alignment and electrical contact via a probe card 20 as described with reference to FIG. 15B.

As already mentioned, a probe card 20 as considered herein may be configured to electrically test more than one semiconductor dice 14 concurrently; more in detail, the array 26 of electrical probes 22 in the probe card 20 may be configured to inject test signals into a set of integrated circuits embedded in one or more semiconductor dice 14, via electrical contact with an array 16 of pad structures 160 that provide electrical contact points to the set of integrated circuits.

In summary, solutions as described with reference to the figures comprise providing a semiconductor wafer 10 having at a surface thereof pad structures 160 providing electrical contact points for a plurality of integrated circuits embedded in the semiconductor wafer 10.

The integrated circuits embedded in the semiconductor wafer 10 are electrically tested via test signals injected thereinto via a probe card 20 comprising an array 16 of electrical probes 22 configured to establish injection paths of test signals to a set of integrated circuits embedded in the semiconductor wafer 10 in response to the array 16 of electrical probes 22 in the probe card 20 aligning and establishing electrical contact with a respective array 16 of pad structures 160 at the surface of the semiconductor wafer 10.

The probe card 20 comprises at least one feedback probe 200 configured to establish coupling with at least one alignment structure 100 at the surface of the semiconductor wafer 10 in response to the array 16 of electrical probes 22 in the probe card 20 being aligned with the respective array 16 of pad structures 160 at the surface of the semiconductor wafer 10 to establish electrical contact therewith.

The coupling of the at least one feedback probe 200 and the at least one alignment structure 100 at the surface of the semiconductor wafer 10 provides feedback on alignment and electrical contact between the array 26 of electrical probes 22 in the probe card 20 and the respective array 16 of pad structures 160 at the surface of the semiconductor wafer 10.

The semiconductor wafer 10 is configured to be partitioned into a plurality of semiconductor dice 14 via cuts at scribe lines SL. In one or more embodiments, the at least one feedback probe 200 in the probe card 20 may be configured to establish coupling with at least one alignment structure 100 located at the scribe lines SL, wherein the at least one alignment structure 100 located at the scribe lines SL is configured to be at least partially removed in response to the semiconductor wafer 10 being partitioned.

In one or more embodiments, the at least one alignment structure 100 comprises an alignment pad 100A having at least one electrically insulating layer thereon (a passivation layer 144 and/or a protective-polyimide, PI-layer 148) provided at the surface of the semiconductor wafer 10.

In such embodiments, the at least one feedback probe 200 may be configured to form a probe mark PM in the at least one electrically insulating layer 144, 148 in response to the array 16 of electrical probes 22 in the probe card 20 being aligned with the respective array 16 of pad structures 160 at the surface of the semiconductor wafer 10 to establish electrical contact therewith. The probe mark PM provides feedback on alignment and electrical contact between the array 26 of electrical probes 22 in the probe card 20 and the corresponding array 16 of pad structures 160 at the surface of the semiconductor wafer 10.

In one or more embodiments, the at least one alignment structure 100 may comprise an alignment pad 100A electrically coupled to ground (as schematically illustrated in FIG. 9 or in FIG. 10). The at least one feedback probe 200 in the probe card 20 may be configured to establish a capacitive coupling with the alignment pad 100A electrically coupled to ground in response to the array 26 of electrical probes 22 in the probe card 20 being aligned with the respective array 16 of pad structures 160 at the surface of the semiconductor wafer 10 to establish electrical contact therewith. Test circuitry 220 associated to the at least one feedback probe 200 is configured to probe (measure, sense or detect, for instance) the capacitive coupling to provide feedback (a measured capacitance C, for instance) on alignment and electrical contact between the array 26 of electrical probes 22 in the probe card 20 and the respective array 16 of pad structures 160.

In one or more embodiments, the at least one alignment structure 100 comprises a first 100A and a second 100B alignment pads electrically coupled via an electrically conductive trace 100C (as illustrated in FIG. 13, for instance). The probe card 20 comprises at least a first 200A and a second 200B feedback probe configured to establish a capacitive coupling with the first 100A and second 100B alignment pads in the at least one test structure 100, respectively, in response to the array 26 of electrical probes 22 in the probe card 20 being aligned with the respective array 16 of pad structures 160 at the surface of the semiconductor wafer 10 to establish electrical contact therewith. Test circuitry (TX test circuitry 220A and RX test circuitry 220B, for instance) associated to the at least first 200A and second 200B feedback probe may be configured to probe (measure, sense or detect, for instance) the capacitive couplings to provide feedback (via measured capacitance values C_{A}, C_{B} for instance) on alignment and electrical contact between the array 26 of electrical probes 22 in the probe card 20 and the respective array 16 of pad structures 160.

In one or more embodiments, the alignment structure 100 at the surface of the semiconductor wafer 10 may comprise a dummy alignment structure 100 electrically decoupled from the plurality of integrated circuits embedded in the semiconductor wafer 10.

Advantageously, the array 26 of electrical probes 22 in the probe card 20 may be aligned and electrically contacted with the respective array 16 of pad structures 160 at the surface of the semiconductor wafer 10 as a function of the feedback (PM; C; C_{A}, C_{B}) provided by the coupling of the at least one feedback probe (200; 200A, 200B) with the at least one alignment structure 100 at the surface of the semiconductor wafer 10.

Without prejudice to the underlying principles, the details and the embodiments may vary, even significantly, with respect to what has been described by way of example only without departing from the scope of the embodiments.

The extent of protection is determined by the annexed claims.

1. A method comprising:
providing a semiconductor wafer having at a surface thereof pad structures providing electrical 1 contact points for a plurality of integrated circuits embedded in the semiconductor wafer, and
electrically testing the plurality of integrated circuits embedded in the semiconductor wafer via test signals injected thereinto via a probe card comprising an array of electrical probes configured to establish injection paths of test signals to a set of integrated circuits embedded in the semiconductor wafer in response to the array of electrical probes in the probe card aligning and establishing electrical contact with a respective array of pad structures at the surface of the semiconductor wafer,
wherein the probe card comprises at least one feedback probe configured to establish coupling with at least one alignment structure at the surface of the semiconductor wafer in response to the array of electrical probes in the probe card being aligned with the respective array of pad structures at the surface of the semiconductor wafer to establish electrical contact therewith, wherein the coupling of the at least one feedback probe with the at least one alignment structure at the surface of the semiconductor wafer provides feedback on alignment and electrical contact between the array of electrical probes in the probe card and a corresponding array of pad structures at the surface of the semiconductor wafer.

2. The method of claim 1, wherein the semiconductor wafer is configured to be partitioned into a plurality of semiconductor dice via cuts at scribe lines, and
wherein the at least one feedback probe in the probe card is configured to establish coupling with at least one alignment structure located at the scribe lines, wherein the at least one alignment structure located at the scribe lines is configured to be at least partially removed in response to the semiconductor wafer being partitioned.

3. The method of claim 1, wherein the at least one alignment structure comprises an alignment pad having at least one electrically insulating layer thereon, and
wherein the at least one feedback probe is configured to form a probe mark in the at least one electrically insulating layer at the alignment pad in response to the array of electrical probes in the probe card being aligned with the respective array of pad structures at the surface of the semiconductor wafer to establish electrical contact therewith, wherein the probe mark provides feedback on alignment and electrical contact between the array of electrical probes in the probe card and the respective array of pad structures at the surface of the semiconductor wafer.

4. The method of claim 1, wherein the at least one alignment structure comprises an alignment pad electrically coupled to ground, and
wherein the at least one feedback probe in the probe card is configured to establish a capacitive coupling with the alignment pad electrically coupled to ground in response to the array of electrical probes in the probe card being aligned with the respective array of pad structures at the surface of the semiconductor wafer to establish electrical contact therewith, wherein test circuitry associated to the at least one feedback probe is configured to probe the capacitive coupling to provide feedback on alignment and electrical contact between the array of electrical probes in the probe card and the respective array of pad structures.

5. The method of claim 1, wherein the at least one alignment structure comprises a first alignment pad and a second alignment pad electrically coupled via an electrically conductive trace, and
wherein the probe card comprises on alignment and electrical contact between the array of electrical probes in the probe card and the respective array of pad structures.

6. The method of claim 5, wherein regions of a redistribution layer at the surface of the semiconductor wafer provide the first alignment pad and the second alignment pad as well as the electrically conductive trace in the at least one alignment structure.

7. The method of claim 1, wherein the at least one alignment structure at the surface of the semiconductor wafer comprises a dummy alignment structure electrically decoupled from the plurality of integrated circuits embedded in the semiconductor wafer.

8. The method of claim 1, comprising aligning and electrically contacting the array of electrical probes in the probe card with the respective array of pad structures at the surface of the semiconductor wafer as a function of the feedback provided by the coupling of the at least one feedback probe in the probe card with the at least one alignment structure at the surface of the semiconductor wafer.

9. A test apparatus comprising:
a wafer holder configured to receive a semiconductor wafer having at a surface thereof pad structures providing electrical contact points for a plurality of integrated circuits embedded in the semiconductor wafer, and
a probe card for electrically testing the plurality of integrated circuits embedded in the semiconductor wafer via test signals injected thereinto via the probe card, the probe card comprising an array of electrical probes configured to establish injection paths of test signals to a set of integrated circuits embedded in the semiconductor wafer in response to the array of electrical probes in the probe card aligning and establishing electrical contact with a respective array of pad structures at the surface of the semiconductor wafer,
wherein the probe card comprises at least one feedback probe configured to establish coupling with at least one alignment structure at the surface of the semiconductor wafer in response to the array of electrical probes in the probe card being aligned with the respective array of pad structures at the surface of the semiconductor wafer to establish electrical contact therewith, wherein the coupling of the at least one feedback probe and a respective alignment structure of the at least one alignment structure at the surface of the semiconductor wafer feedback provides on alignment and electrical contact between the array of electrical probes in the probe card and the respective array of pad structures at the surface of the semiconductor wafer.

10. The test apparatus of claim 9, wherein:
the semiconductor wafer is configured to be partitioned into a plurality of semiconductor dice via cuts at scribe lines, and
the at least one feedback probe in the probe card is configured to establish coupling with at least one alignment structure located at the scribe lines, wherein the at least one alignment structure located at the scribe lines is configured to be at least partially removed in response to the semiconductor wafer being partitioned.

11. The test apparatus of claim 9, wherein the at least one alignment structure comprises an alignment pad having at least one electrically insulating layer thereon, and
wherein the at least one feedback probe is configured to form a probe mark in the at least one electrically insulating layer on the alignment pad in response to the array of electrical probes in the probe card being aligned with the respective array of pad structures at the surface of the semiconductor wafer to establish electrical contact therewith, wherein the probe mark provides feedback on alignment and electrical contact between the array of electrical probes in the probe card and the respective array of pad structures at the surface of the semiconductor wafer.

12. The test apparatus of claim 9, wherein the at least one alignment structure comprises an alignment pad electrically coupled to ground, and
wherein the at least one feedback probe in the probe card is configured to establish a capacitive coupling with the alignment pad electrically coupled to ground in response to the array of electrical probes in the probe card being aligned with the respective array of pad structures at the surface of the semiconductor wafer to establish electrical contact therewith, wherein test circuitry associated to the at least one feedback probe is configured to probe the capacitive coupling to provide feedback on alignment and electrical contact between the array of electrical probes in the probe card and the respective array of pad structures.

13. The test apparatus of claim 9, wherein the at least one alignment structure comprises a first alignment pad and a second alignment pad electrically coupled via an electrically conductive trace, and
wherein the probe card comprises at least a first feedback probe and a second feedback probe configured to establish a capacitive coupling with, respectively, the first alignment pad and the second alignment pad in the at least one alignment structure in response to the array of electrical probes in the probe card being aligned with the respective array of pad structures at the surface of the semiconductor wafer to establish electrical contact therewith, wherein test circuitry associated to at least the first feedback probe and the second feedback probe is configured to probe the capacitive coupling to provide feedback on alignment and electrical contact between the array of electrical probes in the probe card and the respective array of pad structures.

14. The test apparatus of claim 9, wherein the test apparatus is configured for aligning and electrically contacting the array of electrical probes in the probe card with the respective array of pad structures at the surface of the semiconductor wafer as a function of the feedback provided by the coupling of the at least one feedback probe with the at least one alignment structure at the surface of the semiconductor wafer.

15. A probe card for use in the method of claim 1, wherein the probe card comprises:
an array of electrical probes configured to establish injection paths of test signals to a set of integrated circuits embedded in a semiconductor wafer in response to the array of electrical probes in the probe card aligning and establishing electrical contact with a respective array of pad structures at the surface of the semiconductor wafer, and
at least one feedback probe configured to establish coupling with at least one alignment structure at the surface of the semiconductor wafer in response to the array of electrical probes in the probe card being aligned with the respective array of pad structures at the surface of the semiconductor wafer to establish electrical contact therewith, wherein the coupling of the at least one feedback probe and the at least one alignment structure at the surface of the semiconductor wafer provides feedback on alignment and electrical contact between the array of electrical probes in the probe card and the respective array of pad structures at the surface of the semiconductor wafer.

16. A probe card for use in the test apparatus of claim 9, wherein the probe card comprises:
an array of electrical probes configured to establish injection paths of test signals to a set of integrated circuits embedded in a semiconductor wafer in response to the array of electrical probes in the probe card aligning and establishing electrical contact with a respective array of pad structures at the surface of the semiconductor wafer, and
at least one feedback probe configured to establish coupling with at least one alignment structure at the surface of the semiconductor wafer in response to the array of electrical probes in the probe card being aligned with the respective array of pad structures at the surface of the semiconductor wafer to establish electrical contact therewith, wherein the coupling of the at least one feedback probe and the at least one alignment structure at the surface of the semiconductor wafer provides feedback on alignment and electrical contact between the array of electrical probes in the probe card and the respective array of pad structures at the surface of the semiconductor wafer.

17. A semiconductor wafer for use in the method of claim 1, comprising:
pad structures at a surface thereof, the pad structures providing electrical contact points for a plurality of integrated circuits embedded in the semiconductor wafer, and
at least one alignment structure at the surface of the semiconductor wafer,
wherein the semiconductor wafer is configured for having the plurality of integrated circuits embedded in the semiconductor wafer electrically tested via test signals injected thereinto via a probe card comprising an array of electrical probes configured to establish injection paths of test signals to a set of integrated circuits embedded in the semiconductor wafer in response to the array of electrical probes in the probe card aligning and establishing electrical contact with a respective array of pad structures at the surface of the semiconductor wafer, and wherein the probe card comprises at least one feedback probe configured to establish coupling with the at least one alignment structure at the surface of the semiconductor wafer in response to the array of electrical probes in the probe card being aligned with the respective array of pad structures at the surface of the semiconductor wafer to establish electrical contact therewith, wherein the coupling of the at least one feedback probe with the at least one alignment structure at the surface of the semiconductor wafer provides feedback on alignment and electrical contact between the array of electrical probes in the probe card and the corresponding array of pad structures at the surface of the semiconductor wafer.

18. A semiconductor wafer for use in the test apparatus of claim 9, comprising:
pad structures at a surface thereof, the pad structures providing electrical contact points for a plurality of integrated circuits embedded in the semiconductor wafer, and
at least one alignment structure at the surface of the semiconductor wafer,
wherein the semiconductor wafer is configured for having the plurality of integrated circuits embedded in the semiconductor wafer electrically tested via test signals injected thereinto via a probe card comprising an array of electrical probes configured to establish injection paths of test signals to a set of integrated circuits embedded in the semiconductor wafer in response to the array of electrical probes in the probe card aligning and establishing electrical contact with a respective array of pad structures at the surface of the semiconductor wafer, and wherein the probe card comprises at least one feedback probe configured to establish coupling with the at least one alignment structure at the surface of the semiconductor wafer in response to the array of electrical probes in the probe card being aligned with the respective array of pad structures at the surface of the semiconductor wafer to establish electrical contact therewith, wherein the coupling of the at least one feedback probe with the at least one alignment structure at the surface of the semiconductor wafer provides feedback on alignment and electrical contact between the array of electrical probes in the probe card and a corresponding array of pad structures at the surface of the semiconductor wafer.
